(19) United States
(12) Patent Application Publication
(10) Pub. No.: US 2017/0040187 A1
(43) Pub. Date: Feb. 9, 2017

(54) SEALING SHEET PROVIDED WITH DOUBLE-SIDED SEPARATOR, AND METHOD FOR MANUFACTURING SEMICONDUCTOR DEVICE

(71) Applicant: NITTO DENKO CORPORATION, Ibaraki-shi (JP)

(72) Inventors: Chie Iino, Ibaraki-shi (JP); Tsuyoshi Ishizaka, Ibaraki-shi (JP); Kosuke Morita, Ibaraki-shi (JP); Goji Shiga, Ibaraki-shi (JP)

(21) Appl. No.: 15/106,909

(22) PCT Filed: Dec. 22, 2014
(86) PCT No.: PCT/JP2014/083928

§ 371 Date: Jun. 21, 2016

(30) Foreign Application Priority Data
Dec. 26, 2013 (JP) 2013-270259

(51) Int. Cl. H01L 21/56; H01L 23/498; H01L 21/78; C09J 183/04; H01L 23/29; C09J 163/00; C09J 7/02; H01L 21/683; H01L 23/31

(52) U.S. Cl. CPC H01L 21/568; H01L 21/6836; H01L 23/49838; H01L 21/561; H01L 21/78; H01L 23/3121; H01L 23/293; C09J 163/00; C09J 7/0228; C09J 183/04; C09J 7/0282; H01L 2221/68386

(57) ABSTRACT

A sealing sheet with a double-sided separator, provided with a sealing sheet, a separator (A) laminated on one side of the sealing sheet, and a separator (B) laminated on the other side of the sealing sheet, the separation force F1 between the sealing sheet and the separator (A), the separation force F2 between the sealing sheet and the separator (B), the thickness t of the sealing sheet, and the area A of the sealing sheet satisfying a specific relationship.

### TECHNICAL FIELD

The present invention relates to a sealing sheet with separators on both surfaces and a method for manufacturing a semiconductor device.

### BACKGROUND ART

As a method for manufacturing a semiconductor device, a method has been conventionally known of sealing one or more semiconductor chips fixed to a substrate, etc. with a sealing resin and dicing the sealed body to form a packaged semiconductor device unit. For example, a sealing sheet constituted with a thermosetting resin has been known as the sealing resin (for example, refer to Patent Document 1).

### PRIOR ART DOCUMENT

### Patent Document

Patent Document 1: JP-A-2006-19714

### DISCLOSURE OF THE INVENTION

### Problems to be Solved by the Invention

Both surfaces of the sealing sheet described above are normally covered with separators before use. While being used, the separator on one surface is peeled, and after the prescribed steps, the separator on the other surface is peeled. However, there has been a problem that the sealing sheet is broken when peeling the separators.

The present invention has been made in consideration of the above-described problem, and an object thereof is to provide a sealing sheet with separators on both surfaces capable of suppressing breaking of the sealing sheet from occurring when peeling the separators, and a method for manufacturing a semiconductor device using the sealing sheet with separators on both surfaces.

### Means for Solving the Problems

The inventors of the present invention have keenly examined the problem. As a result, it has been found that breaking of the sealing sheet when peeling the separators can be suppressed if the peel strengths of the separators satisfies a specific relationship, and the prevent invention has been completed.

That is, the present invention is a sealing sheet with separators on both surfaces and characterized to have a sealing sheet, a separator A laminated on one surface of the sealing sheet, and a separator B laminated on the other surface of the sealing sheet; and satisfy the following formula (1) when the peel strength between the sealing sheet and the separator A is F1, the peel strength between the sealing sheet and the separator B is F2, the thickness of the sealing sheet is t, and the area of the sealing sheet is A:

0<F2(N/20mm)×A(m²)×t(mm)<10.0(wherein,F1<F2 is satisfied.) (1)

According to the above-described configuration, because the formula (1) is satisfied, breaking of the sealing sheet is suppressed when peeling the separator B. The inventors of the present invention have found that ease of breaking the sealing sheet relates to not only the peel strengths between the sealing sheet and the separators but also the thickness and area of the sealing sheet. It has been found that the larger the thickness t, the easier the sealing sheet is broken; and the larger the area A, the easier the sealing sheet is broken when peeling the separators. It has been also found that breaking of the sealing sheet can be suppressed during peeling the separator B, when the product of the peel strength F2 between the separator B and the sealing sheet, the thickness t, and the area A of the sealing sheet is less than 10.0. If breaking of the sealing sheet does not occur when peeling the separator B, breaking of the sealing sheet does not occur naturally when peeling the separator A. This is because the peel strength between the separator A and the sealing sheet is smaller than the peel strength between the separator B and the sealing sheet. F1<F2 is a necessary parameter in order to peel the separator A first.

The present invention is a method for manufacturing a semiconductor device characterized to have a step A of preparing a laminate in which a semiconductor chip is fixed on a support, a step B of preparing the sealing sheet with separators on both surfaces, a step C of peeling the separator A from the sealing sheet with separators on both surfaces to obtain a sealing sheet with a separator on one surface, a step D of arranging the sealing sheet with a separator on one surface on the semiconductor chip of the laminate so that the surface where the separator B of the sealing sheet with a separator on one surface is peeled faces the surface of the semiconductor chip of the laminate, a step E of embedding the semiconductor chip in the sealing sheet to form a sealed body in which the semiconductor chip is embedded in the sealing sheet, and a step F of peeling the separator B.

According to the above-described configuration, the separator A is peeled from the sealing sheet with separators on both surfaces to form the sealed body, and the separator B is peeled. Because the sealing sheet with separators on both surfaces satisfies the formula (1), breaking of the sealing sheet is suppressed when peeling the separators A and B. Therefore, the yield of the semiconductor device manufactured using the sealing sheet with separators on both surfaces can be improved.

### Effect of the Invention

The present invention can provide a sealing sheet with separators on both surfaces capable of suppressing breaking of the sealing sheet from occurring when peeling the separators, and a method for manufacturing a semiconductor device using the sealing sheet with separators on both surfaces.

### BRIEF DESCRIPTION OF THE DRAWINGS

FIG. 1 is a schematic cross section of a sealing sheet with separators on both surfaces according to the present embodiment.

FIG. 2 is a schematic cross section for explaining a method for manufacturing a semiconductor device according to the present embodiment.

FIG. 3 is a schematic cross section for explaining a method for manufacturing a semiconductor device according to the present embodiment.

FIG. 4 is a schematic cross section for explaining a method for manufacturing a semiconductor device according to the present embodiment.

FIG. 5 is a schematic cross section for explaining a method for manufacturing a semiconductor device according to the present embodiment.

FIG. 6 is a schematic cross section for explaining a method for manufacturing a semiconductor device according to the present embodiment.

FIG. 7 is a schematic cross section for explaining a method for manufacturing a semiconductor device according to the present embodiment.

FIG. 8 is a schematic cross section for explaining a method for manufacturing a semiconductor device according to the present embodiment.

FIG. 9 is a schematic cross section for explaining a method for manufacturing a semiconductor device according to the present embodiment.

FIG. 10 is a schematic cross section for explaining a method for manufacturing a semiconductor device according to the present embodiment.

### MODE FOR CARRYING OUT THE INVENTION

The embodiments of the present invention will be explained below by referring the drawings. However, the present invention is not limited to only these embodiments.

(Sealing Sheet with Separators on Both Surfaces)

FIG. 1 is a schematic cross section of a sealing sheet 10 with separators on both surfaces according to the present embodiment. As shown in FIG. 1, the sealing sheet 10 with separators on both surfaces has a sealing sheet 11, a separator 16a laminated on one surface of the sealing sheet 11, and a separator 16b laminated on the other surface of the sealing sheet 11. The separator 16a corresponds to a separator A of the present invention. The separator 16b corresponds to a separator B of the present invention.

The sealing sheet 10 with separators on both surfaces satisfies the following formula (1) when the peel strength between the sealing sheet 11 and the separator 16a is F1, the peel strength between the sealing sheet 11 and the separator 16b is F2, the thickness of the sealing sheet 11 is t, and the area of the sealing sheet 11 is A:

0<F2(N/20mm)×A(m²)×t(mm)<10.0(wherein,F1<F2 is satisfied.) (1)

Because the sealing sheet 10 with separators on both surfaces satisfies the formula (1), breaking of the sealing sheet 11 is suppressed when peeling the separators 16a and 16b.

The formula (1) preferably satisfies the following (1-1).

1.0×10^{-7<}F2(N/20mm)×A(m²)×t(m)<5.0 (1-1)

The thickness of the separator 16a is not particularly limited; however, it is preferably 50 μm or more, and more preferably 75 μm or more from a viewpoint of prevention of warping that is supposed to easily occur when the area of the sealing sheet 11 is large. From a viewpoint of ease of peeling of the separator, the thickness is preferably 300 μm or less, and more preferably 200 μm or less.

The thickness of the separator 16b is not particularly limited; however, it is preferably 10 μm or more, and more preferably 25 μm or more from a viewpoint of the handleability when peeling the separator. From a viewpoint of ease of peeling of the separator, the thickness is preferably 200 μm or less, and more preferably 100 μm or less.

An example of the separators 16a and 16b that can be appropriately used is a foliate body including a paper base such as paper; a fiber base such as cloth, unwoven fabric, felt, and a net; a metal base such as a metal foil and a metal plate; a plastic base such as a plastic sheet; a rubber base such as a rubber sheet; a foamed body such as a foamed sheet; and a laminate thereof (particularly, a laminate of a plastic base and other bases, a laminate of plastic sheets, etc.) In the present invention, a plastic base can be suitably used. Examples of a material of the plastic base include an olefin resin such as polyethylene (PE), polypropylene (PP), and an ethylene-propylene copolymer; a copolymer having ethylene as a monomer component such as an ethylene-vinylacetate copolymer (EVA), an ionomer resin, an ethylene-(meth)acrylate copolymer, and an ethylene-(meth)acrylate (random, alternate) copolymer; polyester such as polyethylene terephthalate (PET), polyethylene naphthalate (PEN), and polybutylene terephthalate (PBT); an acrylic resin; polyvinylchloride (PVC); polyurethane; polycarbonate; polyphenylenesulfide (PPS); an amide resin such as polyamide (nylon) and wholly aromatic polyamide (aramide); polyetheretherketone (PEEK); polyimide; polyetherimide; polyvinylidene chloride; ABS (an acrylonitrile-butadiene-styrene copolymer); a cellulose resin; a silicone resin; and a fluororesin. The separator 16a may be a single layer or a multiple layer having two or more layers. The separator 16a can be formed with a conventionally known method.

The separators 16a and 16b may be release-treated or may not be release-treated within a range where the formula (1) is satisfied. For example, when the same material is used in both the separators 16a and 16b, the formula (1) may be satisfied according to whether or not the release treatment is performed.

Examples of the releasing agent used in the release treatment include a fluorine-based releasing agent, a long chain alkylacrylate-based releasing agent, and a silicone-based releasing agent. Among these, a silicone-based releasing agent is preferable.

The size and shape of the sealing sheet 10 with separators on both surfaces in planar view are not particularly limited; however, a rectangle having a length of each side of 300 mm or more or a rectangle having a length of each side of 500 mm or more is preferred. In addition, the sealing sheet 10 with separators on both surfaces can have a circular shape having a diameter of 200 mm or more. Particularly, when a sealing sheet with separators on both surfaces has a large area, warping of the sheet easily occurs. However, even if the sealing sheet 10 with separators on both surfaces according to the present embodiment has a large area, warping can be easily suppressed when the thickness of the separator 16a is 50 μm or more.

### (Sealing Sheet)

The constituent material of the sealing sheet 11 preferably contains an epoxy resin, and a phenolic resin as a curing agent. According to this case, the sheet 10 can gain a good thermosetting property.

The epoxy resin is not especially limited. For example, various kinds of epoxy resins can be used such as a triphenylmethane-type epoxy resin, a cresol novolac-type epoxy resin, a biphenyl-type epoxy resin, a modified bisphenol A-type epoxy resin, a bisphenol A-type epoxy resin, a bisphenol F-type epoxy resin, a modified bisphenol F-type epoxy resin, a dicyclopentadiene-type epoxy resin, a phenol novolac-type epoxy resin, and a phenoxy resin. These epoxy resins may be used alone or in combination of two or more thereof.

From the viewpoint of securing the toughness of the epoxy resin after curing and the reactivity of the epoxy resin, epoxy resins are preferable which are solid at normal temperature and have an epoxy equivalent of 150 to 200 and a softening point or melting point of 50 to 130° C. Among these epoxy resins, a triphenylmethane-type epoxy resin, a cresol novolac-type epoxy resin, and a biphenyl-type epoxy resin are more preferable from the viewpoint of reliability.

The phenol resin is not especially limited as long as it initiates curing reaction with the epoxy resin. For example, there can be used a phenol novolac resin, a phenolaralkyl resin, a biphenylaralkyl resin, a dicyclopentadiene-type phenol resin, a cresol novolac resin, a resol resin, etc. These phenol resins may be used alone or in combination of two or more thereof.

From the viewpoint of the reactivity with the epoxy resin, phenol resins are preferably used which have a hydroxy group equivalent of 70 to 250 and a softening point of 50 to 110° C. Among these phenol resins, a phenol novolac resin is more preferably used from the viewpoint of its high curing reactivity. Further, phenol resins having low moisture absorbability can be also preferably used such as a phenolaralkyl resin and a bisphenylaralkyl resin from the viewpoint of reliability.

For the compounding ratio of the phenol resin to the epoxy resin, the epoxy resin and the phenol resin are preferably compounded so that the total amount of the hydroxy group in the phenol resin is 0.7 to 1.5 equivalents, and more preferably 0.9 to 1.2 equivalents, to 1 equivalent of the epoxy group in the epoxy resin.

The total content of the epoxy resin and the phenol resin in the sealing sheet 11 is preferably 2.5% by weight or more, and more preferably 3.0% by weight or more. If the content is 2.5% by weight or more, good adhering strength to the semiconductor chips 23 and the semiconductor wafer 22 can be obtained. The total content of the epoxy resin and the phenol resin in the sealing sheet 11 is preferably 20% by weight or less, and more preferably 10% by weight or less. If the content is 20% by weight or less, moisture absorbability can be decreased.

The sealing sheet 11 may contain a thermoplastic resin. This makes it possible to provide a handling property when the sealing sheet 11 is uncured and low stress property to the cured product.

Examples of the thermoplastic resin include natural rubber, butyl rubber, isoprene rubber, chloroprene rubber, an ethylene-vinylacetate copolymer, an ethylene-acrylic acid copolymer, an ethylene-acrylate copolymer, a polybutadiene resin, a polycarbonate resin, a thermoplastic polyimide resin, polyamide resins such as 6-nylon and 6,6-nylon, a phenoxy resin, an acrylic resin, saturated polyester resins such as PET and PBT, a polyamideimide resin, a fluororesin, and a styrene-isobutylene-styrene block copolymer. These thermoplastic resins may be used alone or in combination of two or more thereof. Among these, a styrene-isobutylene-styrene block copolymer is preferable from the viewpoint of its low stress property and low moisture absorption.

The content of the thermoplastic resin in the sealing sheet 11 may be 1.5% by weight or more, or 2.0% by weight or more. If the content is 1.5% by weight or more, the flexibility can be obtained. The content of the thermoplastic resin in the sealing sheet 11 is preferably 6% by weight or less, and more preferably 4% by weight or less. If the content is 4% by weight or less, the adhesion with the semiconductor chips 23 and the semiconductor wafer 22 is good.

The sealing sheet 11 preferably contains an inorganic filler.

The inorganic filler is not especially limited, and various kinds of conventionally known fillers can be used. Examples thereof include powers of quartz glass, talc, silica (such as fused silica and crystalline silica), alumina, aluminum nitride, silicon nitride, and boron nitride. These may be used alone or in combination of two or more kinds. Among these, silica and alumina are preferable, and silica is more preferable due to the reason that the linear expansion coefficient can be satisfactorily decreased.

As silica, silica powers are preferable, and fused silica powers are more preferable. Examples of the fused silica powders include spherical fused silica powders and crushed and fused silica powders. However, spherical fused silica powders are preferable from the viewpoint of fluidity. Among these, powers having an average particle size of 10 to 30 μm are preferable, and powders having an average particle size of 15 to 25 μm are more preferable.

The average particle size can be obtained, for example, by measurement on a sample that is extracted arbitrarily from the population using a laser diffraction-scattering type particle size distribution measuring apparatus. Among these, silica powders are preferable having an average particle size of 10 μm to 30 μm, and more preferable having an average particle size of 15 μm to 25 μm.

For example, the average particle size can be measured by using a laser diffraction-scattering type particle size distribution measuring apparatus on a sample that is arbitrarily extracted from the population.

The content of the inorganic filler in the sealing sheet 11 is preferably 75% by weight to 95% by weight, and more preferably 78% by weight to 95% by weight relative to the total content of the sealing sheet 11. If the content of the inorganic filler is 75% by weight or more relative to the total content of the sealing sheet 11, the thermal expansion coefficient can be kept low, and thus mechanical damage due to thermal impact can be suppressed. On the other hand, if the content of the inorganic filler is 95% by weight or less relative to the total content of the sealing sheet 11, the flexibility, the fluidity, and the adhesion become more satisfactory.

The sealing sheet 11 preferably contains a curing accelerator.

The curing accelerator is not especially limited as long as it promotes curing of the epoxy resin and the phenol resin, and examples of the curing accelerator include organophosphate compounds such as triphenylphosphine and tetraphenylphosphonium tetraphenylborate; and imidazole compounds such as 2-phenyl-4,5-dihydroxymethylimidazole and 2-phenyl-4-methyl-5-hydroxymethylimidazole. Among these, 2-phenyl-4,5-dihydroxymethylimidazole is preferable due to the reason that the curing reaction does not rapidly proceed even when the temperature increases during kneading and the sealing sheet 11 can be produced satisfactorily.

The content of the curing accelerator is preferably 0.1 to 5 parts by weight to the total 100 parts by weight of the epoxy resin and the phenol resin.

The sealing sheet 11 preferably contains a flame retardant component. This makes it possible to reduce an expansion of combustion when the sealing sheet 11 catches fire due to short circuit of the parts or heat generation. Examples of the flame retardant component include various kinds of metal hydroxides such as aluminum hydroxide, magnesium hydroxide, iron hydroxide, calcium hydroxide, tin hydroxide, and composite metal hydroxide; and a phosphazene flame retardant.

From the viewpoint of exhibiting flame retardancy even with a small amount, the content of phosphorus element in the phosphazene flame retardant is preferably 12% by weight or more.

The content of the flame retardant component in the sealing sheet 11 is preferably 10% by weight or more, and more preferably 15% by weight or more in the entire organic component (excluding inorganic filler). If the content is 10% by weight or more, the flame retardancy can be obtained satisfactorily. The content of the thermoplastic resin in the sealing sheet 11 is preferably 30% by weight or less, and more preferably 25% by weight or less. If the content is 30% by weight or less, deterioration in the physical properties (deterioration in physical properties such as glass transition temperature and resin strength at high temperature) of the cured product tends to be suppressed.

The sealing sheet 11 preferably contains a silane coupling agent. The silane coupling agent is not especially limited, and an example includes 3-glycidoxypropyl trimethoxysilane.

The content of the silane coupling agent in the sealing sheet 11 is preferably 0.1 to 3% by weight. If the content is 0.1% by weight or more, the strength of the cured product is sufficiently made high, so that the water absorption can be lowered. If the content is 3% by weight or less, the amount of outgas can be decreased.

The sealing sheet 11 is preferably colored. With this configuration, The sealing sheet 11 can exhibit an excellent marking property and an excellent appearance, and a semiconductor device can be obtained having an appearance with added value. Because the colored sealing sheet 11 has an excellent marking property, various information such as character information and pattern information can be given by marking. Especially, the information such as character information and pattern information that is given by marking can be recognized visually with excellent visibility by controlling the color. It is possible to color-code the sealing sheet 11 by product, for example. When the sealing sheet 11 is colored (when it is not colorless or transparent), the color is not especially limited. However, the color is preferably a dark color such as black, blue, or red, and black is especially preferable.

In this embodiment, the dark color means a dark color having L* that is defined in the L*a*b* color system of basically 60 or less (0 to 60), preferably 50 or less (0 to 50) and more preferably 40 or less (0 to 40).

The black color means a blackish color having L* that is defined in the L*a*b* color system of basically 35 or less (0 to 35), preferably 30 or less (0 to 30) and more preferably 25 or less (0 to 25). In the black color, each of a* and b* that is defined in the L*a*b* color system can be appropriately selected according to the value of L*. For example, both of a* and b* are preferably −10 to 10, more preferably −5 to 5, and especially preferably −3 to 3 (above all, 0 or almost 0).

In this embodiment, L*, a*, and b* that are defined in the L*a*b* color system can be obtained by measurement using a colorimeter (tradename: CR-200 manufactured by Konica Minolta Holdings, Inc.). The L*a*b* color system is a color space that is endorsed by Commission Internationale de I'Eclairage (CIE) in 1976, and means a color space that is called a CIE1976 (L*a*b*) color system. The L*a*b* color system is provided in JIS Z 8729 in the Japanese Industrial Standards.

When the sealing sheet 11 is colored, a coloring material (colorant) is usable in accordance with a target color. The sheet of the present invention for sealing may be made of a single layer or made of plural layers. It is preferred that the colorant is added at least to the side of the sheet surface opposite to the sheet surface that faces the semiconductor wafer. Specifically, when the sealing sheet is made of a single layer, the colorant may be evenly contained in the whole of the sealing sheet, or may be contained to be unevenly distributed in the side of the sheet surface opposite to the sheet surface that faces the semiconductor wafer. When the sealing sheet is made of plural layers, it is permissible to add the colorant to a layer at the side of the sheet surface opposite to the sheet surface that faces the semiconductor wafer, and further not to add the colorant to the other layer (s). In the present embodiment, a description will be made hereinafter about a case where the sheet of the present invention for sealing is the sealing sheet that is a sheet made of a single layer. When the colorant is added to the side of the sheet surface opposite to the sheet surface that faces the semiconductor wafer in the sealing sheet, a region of the sheet which has been laser-marked can be improved in visibility. Various dark color materials such as black color materials, blue color materials, and red color materials can be suitably used, and especially the black color materials are suitable. The color materials may be any of pigments, dyes, and the like. The color materials can be used alone or two types or more can be used together. Any dyes such as acid dyes, reactive dyes, direct dyes, dispersive dyes, and cationic dyes can be used. The pigments are also not especially limited in the form, and may be appropriately selected from known pigments.

The use of, in particular, the dye as the coloring material puts the sealing sheet 11 into a state that the dye is evenly or substantially evenly dissolved or dispersed in the sheet 10, so that the sealing sheet 11 can easily be produced with an even or substantially even color density to be improved in markability and external appearance.

The black color material is not especially limited, and can be appropriately selected from inorganic black pigments and black dyes, for example. The black color material may be a color material mixture in which a cyan color material (blue-green color material), a magenta color material (red-purple color material), and a yellow color material are mixed together. The black color materials can be used alone or two types or more can be used together. The black color materials can be used also with other color materials other than black.

Specific examples of the black color materials include carbon black such as furnace black, channel black, acetylene black, thermal black, and lamp black, graphite (black lead), copper oxide, manganese dioxide, azo pigments such as azomethine azo black, aniline black, perylene black, titanium black, cyanine black, activated carbon, ferrite such as nonmagnetic ferrite and magnetic ferrite, magnetite, chromium oxide, iron oxide, molybdenum disulfide, chromium complex, complex oxide black, and anthraquinone organic black.

In the present invention, black dyes such as C. I. solvent black 3, 7, 22, 27, 29, 34, 43, and 70, C. I. direct black 17, 19, 22, 32, 38, 51, and 71, C. I. acid black 1, 2, 24, 26, 31, 48, 52, 107, 109, 110, 119, and 154, and C. I. disperse black 1, 3, 10, and 24; and black pigments such as C. I. pigment black 1 and 7 can be used as the black color material.

Examples of such black color materials that are available on the market include Oil Black BY, Oil Black BS, Oil Black HBB, Oil Black 803, Oil Black 860, Oil Black 5970, Oil Black 5906, and Oil Black 5905 manufactured by Orient Chemical Industries Co., Ltd.

Examples of color materials other than the black color materials include a cyan color material, a magenta color material, and a yellow color material. Examples of the cyan color material include cyan dyes such as C. I. solvent blue 25, 36, 60, 70, 93, and 95; and C. I. acid blue 6 and 45; and cyan pigments such as C. I. pigment blue 1, 2, 3, 15, 15:1, 15:2, 15:3, 15:4, 15:5, 15:6, 16, 17, 17:1, 18, 22, 25, 56, 60, 63, 65, and 66; C. I. vat blue 4 and 60; and C. I. pigment green 7.

Examples of the magenta color material include magenta dyes such as C. I. solvent red 1, 3, 8, 23, 24, 25, 27, 30, 49, 52, 58, 63, 81, 82, 83, 84, 100, 109, 111, 121, and 122; C. I. disperse red 9; C. I. solvent violet 8, 13, 14, 21, and 27; C. I. disperse violet 1; C. I. basic red 1, 2, 9, 12, 13, 14, 15, 17, 18, 22, 23, 24, 27, 29, 32, 34, 35, 36, 37, 38, 39, and 40; and C. I. basic violet 1, 3, 7, 10, 14, 15, 21, 25, 26, 27, and 28.

Examples of the magenta color material include magenta pigments such as C. I. pigment red 1, 2, 3, 4, 5, 6, 7, 8, 9, 10, 11, 12, 13, 14, 15, 16, 17, 18, 19, 21, 22, 23, 30, 31, 32, 37, 38, 39, 40, 41, 42, 48:1, 48:2, 48:3, 48:4, 49, 49:1, 50, 51, 52, 52:2, 53:1, 54, 55, 56, 57:1, 58, 60, 60:1, 63, 63:1, 63:2, 64, 64:1, 67, 68, 81, 83, 87, 88, 89, 90, 92, 101, 104, 105, 106, 108, 112, 114, 122, 123, 139, 144, 146, 147, 149, 150, 151, 163, 166, 168, 170, 171, 172, 175, 176, 177, 178, 179, 184, 185, 187, 190, 193, 202, 206, 207, 209, 219, 222, 224, 238, and 245; C. I. pigment violet 3, 9, 19, 23, 31, 32, 33, 36, 38, 43, and 50; and C. I. vat red 1, 2, 10, 13, 15, 23, 29, and 35.

Examples of the yellow color material include yellow dyes such as C. I. solvent yellow 19, 44, 77, 79, 81, 82, 93, 98, 103, 104, 112, and 162; and yellow pigments such as C. I. pigment orange 31 and 43, C. I. pigment yellow 1, 2, 3, 4, 5, 6, 7, 10, 11, 12, 13, 14, 15, 16, 17, 23, 24, 34, 35, 37, 42, 53, 55, 65, 73, 74, 75, 81, 83, 93, 94, 95, 97, 98, 100, 101, 104, 108, 109, 110, 113, 114, 116, 117, 120, 128, 129, 133, 138, 139, 147, 150, 151, 153, 154, 155, 156, 167, 172, 173, 180, 185, and 195, and C. I. vat yellow 1, 3, and 20.

Various color materials such as cyan color materials, magenta color materials, and yellow color materials can be used alone or two types or more can be used together. When two types or more of various color materials such as cyan color materials, magenta color materials, and yellow color materials are used, the mixing ratio or the compounding ratio of these color materials is not especially limited, and can be appropriately selected according to the types of each color material and the intended color.

The light transmittance of the sealing sheet 11 to visible rays (wavelength: 380 to 800 nm) (visible light transmittance) is not particularly limited, and ranges, for example, preferably from 20 to 0%, more preferably from 10 to 0%, in particular preferably from 5 to 0%. When the visible light transmittance of the sealing sheet 11 is set to 20% or less, the sheet can be made good in printed-image visibility. Moreover, a bad effect of the passage of rays onto the semiconductor elements can be prevented.

About the visible light transmittance (%) of the sealing sheet 11, the sealing sheet 11 is produced with a thickness (average thickness) of 10 μm, and a product with a trade name “UV-2550” (manufactured by Shimadzu Corporation) is used to radiate visible rays having wavelengths of 380 to 800 nm at a predetermined intensity onto the sheet 10 (thickness: 10 μm) for sealing. The light intensity of the visible rays transmitted through the sealing sheet 11 by this radiation is measured, and then the visible light transmittance is calculated in accordance with the following expression.

Visible light transmittance (%)=(“light intensity of visible rays transmitted through sealing sheet 11”/“initial light intensity of visible rays”×100

This method for calculating the light transmittance (%) is applicable to the light transmittance (%) of the sealing sheet 11 when the sheet has any thickness other than 10 μm. Specifically, in accordance with Lambert-Beer's law, the absorbance A₁₀ thereof when the thickness is 10 μm can be calculated as follows:

A₁₀=α×L₁₀×C (1)

wherein L₁₀ represents the light path length; α, the absorption coefficient; and C, the concentration of the sample.

The absorbance Aₓ of the sample when the thickness thereof is X (μm) can be represented by the following expression (2).

Aₓ=α×Lₓ×C (2)

The absorbance A₂₀ when the thickness is 20 (μm) can be represented by the following expression (3):

A₁₀=−log₁₀T₁₀ (3)

wherein T₁₀ represents the light transmittance when the thickness is 10 μm.

In accordance with the expressions (1) to (3), the absorbance Aₓ can be represented by the following.

Aₓ=A₁₀×(Lₓ/L₁₀)=−[log₁₀(T₁₀)]×(Lₓ/L₁₀)

Using this absorbance, the light transmittance Tₓ (%) when the thickness is X (μm) can be calculated in accordance with the following:

Tₓ=10^{-AX}

wherein Aₓ=−[log₁₀(T₁₀)]×(Lₓ/L₁₀).

In the present embodiment, the thickness (average thickness) of the sealing sheet is 10 μm when the light transmittance (%) of the sealing sheet is gained. However, this thickness of the sealing sheet is merely a thickness used when the light transmittance (%) of the sealing sheet is gained. Thus, it is not meant that the thickness of the sealing sheet is 10 μm in the present invention.

The light transmittance (%) of the sealing sheet 11 is controllable in accordance with the kind and the content of the resin component, those of the colorant (such as the pigment or dye), those of the filler, and others.

Besides the above-mentioned individual components, any other additive may be appropriately blended into the sealing sheet 11, as required.

The thickness of the sealing sheet 11 is not particularly limited, and it is 50 μm to 2,000 μm for example, preferably 70 μm to 1,200 μm, and more preferably 100 μm to 700 μm from the viewpoint of using it as a sealing sheet and in which the semiconductor chip 23 can be suitably embedded.

The method of manufacturing the sealing sheet 11 is not especially limited; however, preferred examples are a method of preparing a kneaded product of the resin composition for forming the sealing sheet 11 and applying the obtained kneaded product and a method of subjecting the obtained kneaded product to plastic-working to be formed into a sheet shape. This makes it possible to produce the sealing sheet 11 without using a solvent. Therefore, the effects on the semiconductor chip 53 from the volatilized solvent can be suppressed.

Specifically, each component described later is melted and kneaded with a known kneader such as a mixing roll, a pressure kneader, or an extruder to prepare a kneaded product, and the obtained kneaded product is applied or plastic-worked into a sheet shape. As a kneading condition, the temperature is preferably the softening point or higher of each component described above, and is for example 30 to 150° C. When the thermal curing property of the epoxy resin is considered, the temperature is preferably 40 to 140° C., and more preferably 60 to 120° C. The time is for example 1 to 30 minutes, and preferably 5 to 15 minutes.

The kneading is preferably performed under a reduced pressure condition (under reduced pressure atmosphere). This makes it possible to remove gas, and to prevent invasion of gas into the kneaded product. The pressure under the reduced pressure condition is preferably 0.1 kg/cm² or less, and more preferably 0.05 kg/cm² or less. The lower limit of the pressure under reduced pressure is not especially limited; however, it is 1×10⁻⁴ kg/cm² or more.

When the kneaded product is applied to form the sealing sheet 11, the kneaded product after being melt-kneaded is preferably applied while it is at high temperature without being cooled. The application method is not especially limited, and examples thereof include bar coating, knife coating, and slot-die coating. The application temperature is preferably the softening point or higher of each component described above. When the thermal curing property and molding property of the epoxy resin are considered, the temperature is for example 40 to 150° C., preferably 50 to 140° C., and more preferably 70 to 120° C.

When forming the sealing sheet 11 by plastic-working the kneaded product, the kneaded product after melt-kneaded is preferably subjected to plastic-working while it is at high temperature without being cooled. The plastic-working process is not especially limited, and examples thereof include flat plate pressing, T-die extrusion, screw-die extrusion, rolling, roll kneading, inflation extrusion, coextrusion, and calendar molding. The temperature for plastic-working is preferably the softening point or higher of each component described above. When the thermal curing property and molding property of the epoxy resin are considered, the temperature is for example 40 to 150° C., preferably 50 to 140° C., and more preferably 70 to 120° C.

The resin, etc. for forming the sealing sheet 11 can be dissolved and dispersed into an appropriate solvent to prepare varnish, and the varnish can be applied to obtain the sealing sheet 11.

Next, the method for manufacturing a semiconductor device using the sealing sheet 10 with separators on both surfaces will be explained.

The method for manufacturing a semiconductor device according to the present embodiment has at least a step A of preparing a laminate in which a semiconductor chip is flip-chip bonded to the circuit formation surface of a semiconductor wafer, a step B of preparing the sealing sheet with separators on both surfaces, a step C of peeling the separator A from the sealing sheet with separators on both surfaces to obtain a sealing sheet with a separator on one surface, a step D of arranging the sealing sheet with a separator on one surface on the semiconductor chips of the laminate so that the surface where the separator B of the sealing sheet with a separator on one surface is peeled faces the surface of the semiconductor chips of the laminate, a step E of embedding the semiconductor chips in the sealing sheet to forma sealed body in which the semiconductor chips are embedded in the sealing sheet, and a step F of peeling the separator B.

The case will be explained in the present embodiment in which “the laminate in which the semiconductor chips are fixed on a support” of the present invention is “a laminate in which the semiconductor chips are flip-chip bonded to the circuit formation surface of the semiconductor wafer”. The present embodiment is what is called a method for manufacturing a semiconductor device using a chip-on-wafer process.

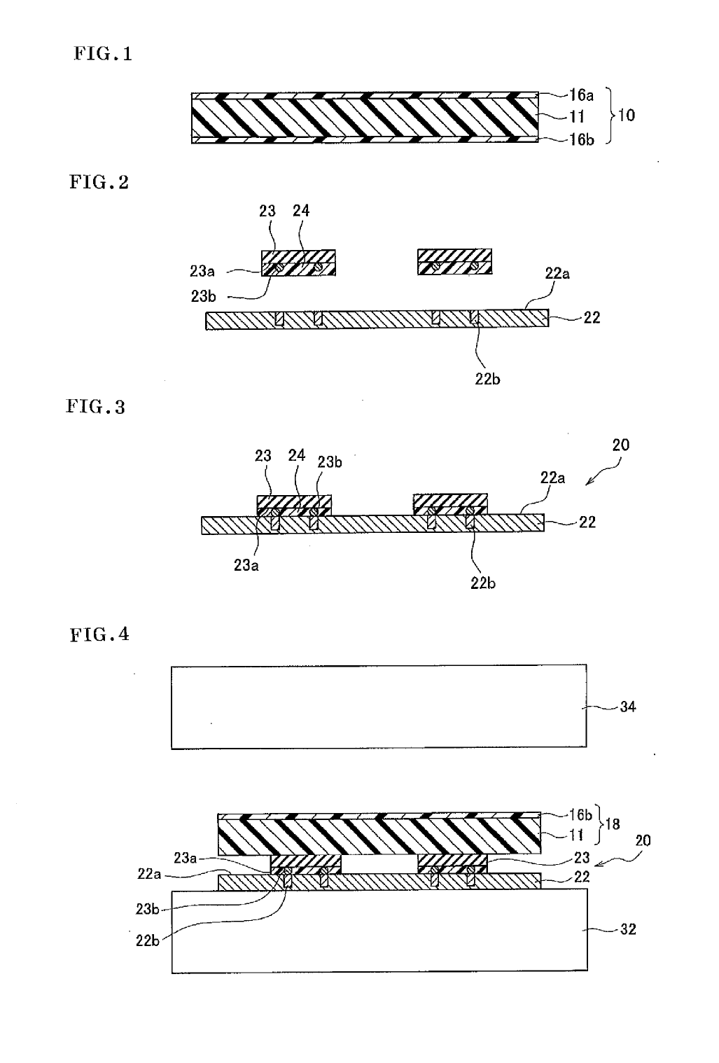

FIGS. 2 to 10 are schematic cross sections for explaining a method for manufacturing a semiconductor device according to the present embodiment.

### [Preparation Step]

In the method for manufacturing a semiconductor device according to the present embodiment, a laminate 20 is first prepared in which a semiconductor chip 23 is flip-chip bonded to a circuit formation surface 22a of a semiconductor wafer 22 (Step A). In the first embodiment, the semiconductor wafer 22 corresponds to “the support” of the present invention. For example, the laminate 20 can be obtained as below.

As shown in FIG. 2, one or a plurality of the semiconductor chips 23 each having a circuit formation surface 23a and the semiconductor wafer 22 having the circuit formation surface 22a are prepared. The case will be explained below in which a plurality of semiconductor chips is flip-chip bonded to a semiconductor wafer. The shape and the size of the semiconductor wafer 22 in planar view can be same as the size and the shape of the sealing sheet 10 with separators on both surfaces in planar view. For example, the size and the shape can be a circular shape having a diameter of 200 mm or more.

Next, as illustrated in FIG. 3, the semiconductor chips 23 are flip-chip bonded to the circuit-forming surface 22a of the semiconductor wafer 22. For the mounting of the semiconductor chips 23 onto the semiconductor wafer 22, a known apparatus is usable, which is, for example, a flip-chip bonder or a die bonder. Specifically, bumps 23b formed in the circuit-forming surface 23a of each of the semiconductor chips 23 are electrically connected to electrodes 22b formed in the circuit-forming surface 22a of the semiconductor wafer 22. This manner makes it possible to yield a laminate 20 in which the semiconductor chips 23 are mounted on the semiconductor wafer 22. At this time, a resin sheet 24 for underfill may be bonded to the circuit-forming surface 23a of each of the semiconductor chips 23. In this case, by flip-chip bonding the semiconductor chips 23 onto c, gaps between the semiconductor chips 23 and the semiconductor wafer 22 can be sealed up with the resin. A method for flip-chip bonding the semiconductor chips 23, to which the resin sheets 24 for underfill are bonded, onto the semiconductor wafer 22 is disclosed in, for example, JP-A-2013-115186; thus, detailed description thereabout is omitted herein.

[Step of Preparing Sealing Sheet with Separators on Both Surfaces]

In the method for manufacturing a semiconductor device according to the present embodiment, the sealing sheet 10 with separators on both surfaces (refer to FIG. 1) is prepared (Step B).

[Step of Peeling Separator A from Sealing Sheet with Separators on Both Surfaces]

As shown in FIG. 4, the separator 16a is peeled from the sealing sheet 10 with separators on both surfaces after the step B to obtain the sealing sheet 18 with a separator on one surface (Step C). The peel strength at the interface between the separator 16b of the sealing sheet 10 with separators on both surfaces and the sealing sheet 11 is sufficient enough to prevent the separators 16a from falling.

[Step of Arranging Sealing Sheet with Separators on One Surface on Laminate]

Next, the laminate 20 is arranged on a lower heating plate 32 with the surface where the semiconductor chip 23 is mounted facing upwards, and the sealing sheet 18 with a separator on one surface is arranged on the semiconductor chip 23 of the laminate 20 so that the surface where the separator 16a of the sealing sheet 18 with a separator on one surface is peeled faces the surface of the semiconductor chip 23 of the laminate 20 as shown in FIG. 4 (Step D).

In this step, the laminate 20 may be arranged on the lower heating plate 32 first, and the sealing sheet 18 with a separator on one surface may be arranged on the laminate 20; or the sealing sheet 18 with separators on one surface may be laminated on the laminate 20 first, and the laminated product in which the sealing sheet 18 with separators on one surface is laminated on the laminate 20 may be arranged on the lower heating plate 32.

### [Step of Forming Sealed Body]

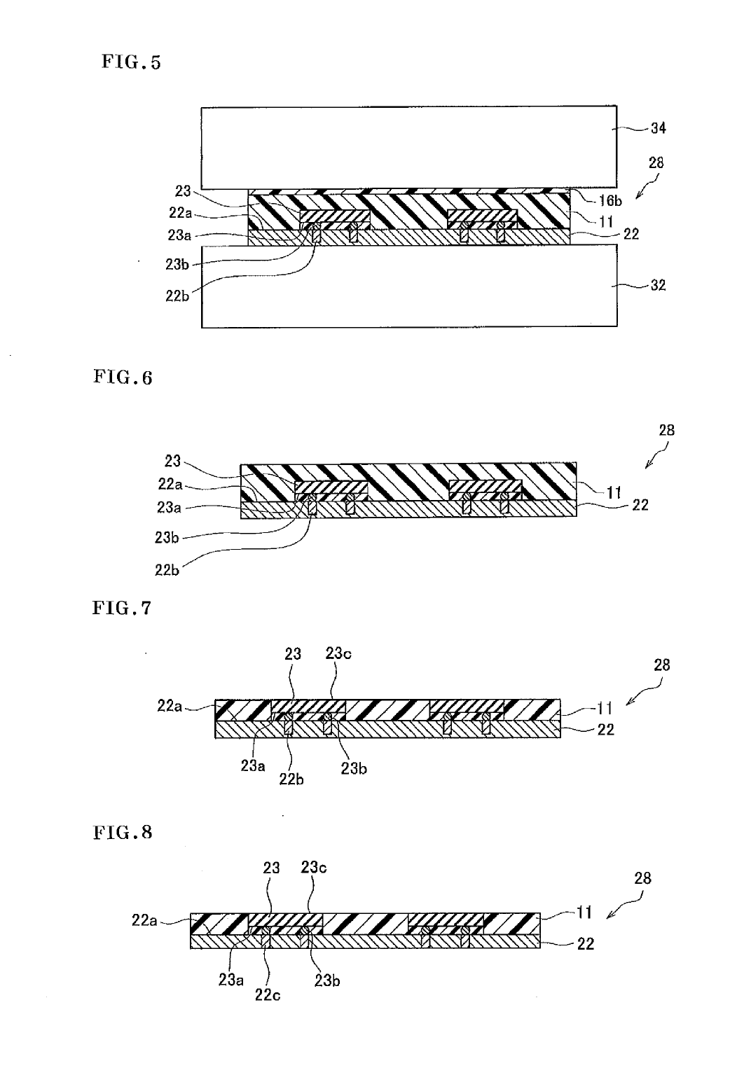

Next, the semiconductor chip 23 is embedded in a resin layer 14 for embedding of the sealing sheet 11 by heat pressing with the lower heating plate 32 and upper heating plate 34 as shown in FIG. 5 to form a sealed body 28 in which the semiconductor chip 23 is embedded in the sealing sheet 11 (Step E).

For the hot pressing condition when the semiconductor chip 23 is embedded into the sealing sheet 11, the temperature is for example 40 to 100° C., and preferably 50 to 90° C.; the pressure is for example 0.1 to 10 MPa, and preferably 0.5 to 0.8 MPa; and the duration is for example 0.3 to 10 minutes, and preferably 0.5 to 5 minutes. This makes it possible to provide a semiconductor device in which the semiconductor chip 23 is embedded in the sealing sheet 11. In consideration of improvement of the tackiness and followability of the sealing sheet 11 to the semiconductor chip 23 and the semiconductor wafer 22, pressing is preferably performed under a reduced pressure condition.

For the reduced pressure condition, the pressure is for example 0.1 to 5 kPa, and preferably 0.1 to 100 Pa; and the reduced pressure maintaining time (time from start of reducing pressure to start of pressing) is for example 5 to 600 seconds, and preferably 10 to 300 seconds.

### [Step of Peeling Release Liner]

Next, the separator 16b is peeled as shown in FIG. 6 (Step F).

### [Thermal Curing Step]

Next, the sealing sheet 11 is thermally cured. Particularly, the resin layer 14 for embedding constituting the sealing sheet 11 is thermally cured. Specifically, for example, the entire sealed body 28 is heated in which the semiconductor chip 23 mounted on the semiconductor wafer 22 is embedded in the sealing sheet 11.

The heating temperature of the thermal curing treatment is preferably 100° C. or more, and more preferably 120° C. or more. On the other hand, the upper limit of the heating temperature is preferably 200° C. or less and more preferably 180° C. or less. The heating time is preferably 10 minutes or more, and more preferably 30 minutes or more. On the other hand, the upper limit of the heating time is preferably 180 minutes or less, and more preferably 120 minutes or less. A pressure is preferably applied in the thermal curing treatment. The pressure is preferably 0.1 MPa or more, and more preferably 0.5 MPa or more. On the other hand, the upper limit thereof is preferably 10 MPa or less, and more preferably 5 MPa or less.

### [Step of Grinding Sealing Sheet]

Next, as illustrated in FIG. 7, the sealing sheet 11 of the sealed body 28 is ground to expose respective rear surfaces 23c of the semiconductor chips 23. The method for grinding the sealing sheet 11 is not particularly limited, and may be, for example, a grinding method using a grinding stone rotatable at a high velocity.

### [Step of Forming Interconnect Layer]

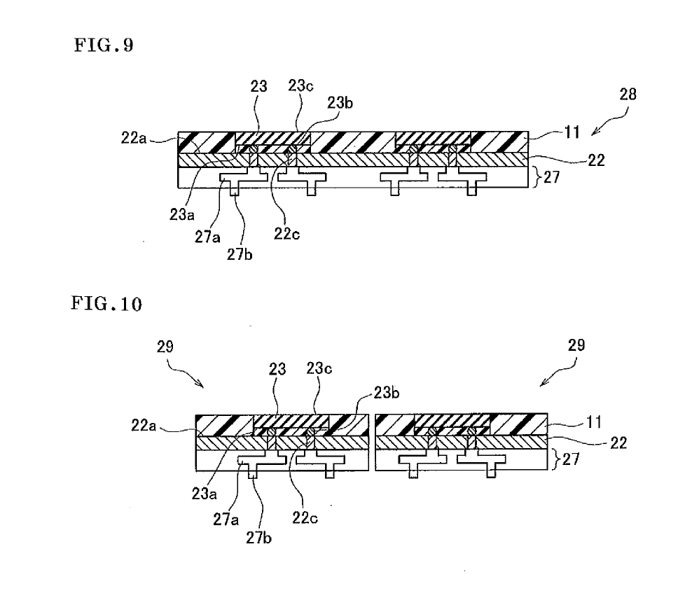

Next, the semiconductor wafer surface opposite to the semiconductor-chip-23-mounted surface of the semiconductor wafer 22 is ground to make vias 22c (see FIG. 8), and then an interconnect layer 27 is formed which has interconnects 27a (see FIG. 9). The method for grinding the semiconductor wafer 22 is not particularly limited, and is, for example, a grinding method using a grinding stone rotatable at a high velocity. Bumps 27b projected from the interconnects 27a may be formed in the interconnect layer 27. It is allowable to apply, to the method of forming the interconnect layer 27, a technique known in the prior art for manufacturing a circuit board or interposer, such as a semi-additive method or a subtractive method. Thus, detailed description thereabout is omitted herein.

### [Dicing Step]

Subsequently, as illustrated in FIG. 10, the sealed body 28 from which the rear surfaces 23c of the semiconductor chips 23 are exposed are diced. Through this step, semiconductor devices 29, which correspond to the respective units of the semiconductor chips 23, can be obtained.

### [Substrate Mounting Step]

As required, a substrate mounting step may be performed in which each of the semiconductor devices 29 is mounted onto a different substrate (not illustrated). For the mounting of the semiconductor device 29 onto the different substrate, a known apparatus such as a flip-chip bonder or die bonder is usable.

According to the method for manufacturing a semiconductor device according to the present embodiment, the separator 16a is peeled from the sealing sheet 10 with separators on both surfaces to form the sealed body 28, and the separator 16b is peeled. Because the sealing sheet 10 with separators on both surfaces satisfies the formula (1), breaking of the sealing sheet is suppressed when peeling the separators 16a and 16b. Therefore, the yield of a semiconductor device 29 manufactured using the sealing sheet 10 with separators on both surfaces can be improved.

The case in which the separator 16a is peeled before the thermal curing step is explained in the present embodiment. However, the separator 16a may be peeled after the thermal curing step.

In the above-described embodiment, the case has been explained in which the method for manufacturing a semiconductor device according to the present invention is what is called a method for manufacturing a semiconductor device using a chip-on-wafer process. That is, the case has been explained in which “the laminate in which the semiconductor chips are fixed on a support” of the present invention is “a laminate in which the semiconductor chips are flip-chip bonded to the circuit formation surface of the semiconductor wafer”.

However, the method for manufacturing a semiconductor device according to the present invention is not limited to this example. The support of the present invention may be a temporary fixing material, and may be removed after the sealed body is formed.

The present invention is not limited to the above-described embodiment. Only the step A, the step B, the step C, the step D, the step E, and the step F have to be performed. Other steps are optional, and they may be performed or may not be performed. In addition, each step may be performed in any order to the extent the order is inconsistent with the purpose of the present invention.

A case has been explained in the above-described embodiment in which the sealing sheet of the sealing sheet with separators on both surfaces is composed of one layer. However, the layer configuration of the sealing sheet of the present invention is not limited to this example, and the sealing sheet may be composed of two or more layers.

### EXAMPLES

Hereinafter, the present invention will be described in detail by way of examples thereof. However, the invention is not limited to the examples as far as any other example does not depart from the subject matters of the present invention. In each of the examples, the word “part(s)” denotes part(s) by weight unless otherwise specified.

### <Production of Sealing Sheet>

The components and their compounding ratios used in the working examples and the comparative examples will be explained.

### <Components>

Epoxy resin: Bisphenol F epoxy resin, epoxy equivalent weight 200 g/eq, softening point 80° C. (trade name “YSLV-80XY” manufactured by Nippon Steel Chemical Co., Ltd.)

Phenol resin: Phenol resin having a biphenylaralkyl skeleton, hydroxyl equivalent weight 203 g/eq, softening point 67° C. (trade name “MEH-7851-SS” manufactured by Meiwa plastic Industries, Ltd.)

Silane coupling agent: 3-glycidoxypropyltrimethoxysilane (trade name “KBM-403” manufactured by Shin-Etsu Chemical Co., Ltd.)

Curing accelerator: 2-phenyl-4,5-dihydroxymethylimidazole (trade name “2PHZ-PW” manufactured by Shikoku Chemicals Corporation)

Thermoplastic resin: Acrylic rubber-based stress-relaxing agent (trade name “J-5800” manufactured by Mitsubishi Rayon Co., Ltd.)

Filler: Fused spherical silica powders, average particle size 17.6 μm (trade name “FB-9454FC” manufactured by Denka Co., Ltd.)

Carbon black: trade name “#20” manufactured by Mitsubishi Chemical Corporation (particle size 50 nm)

### <Compounding Ratio>

(1) The epoxy resin and the phenol resin were compounded so that a hydroxyl group in the phenol resin was 1 equivalent relative to 1 equivalent of epoxy group in the epoxy resin (total amount of the epoxy resin and the phenol resin in 100% by weight of the total compounded components: 9.3% by weight)
(2) The curing accelerator was compounded so that its amount was 1.0 part by weight relative to the total 100 parts by weight of the epoxy resin and the phenol resin.
(3) The thermoplastic resin was compounded so that its amount was 30% by weight in 100% by weight of the organic components (total components excluding the filler).
(4) The filler was compounded so that its amount was 88% by weight in 100% by weight of the total compounded components (79.5% by volume in the resin sheet).
(5) The silane coupling agent was compounded so that its amount was 0.1 parts by weight relative to 100 parts by weight of the filler.
(6) The carbon black was compounded so that its amount was 0.3% by weight in 100% by weight of the total compounded components.

### Example 1

Each of the components was compounded according to the compounding ratio, and the compound was melted and kneaded at 60° C. to 120° C. for 10 minutes under a reduced pressure condition (0.01 kg/cm²) using a roll kneader to prepare a kneaded product. Next, the obtained kneaded product was formed into a sheet with a flat plate press method, and cut into pieces each having a prescribed size. The thicknesses of the sheets were 0.2 mm, 0.5 mm, 1 mm, and 2 mm. Each of the sheets with different thicknesses was cut into pieces each having a size (size in planar view) of 1 cm×1 cm, 10 cm×10 cm, 30 cm×30 cm, or 1 m×1 m to obtain a sealing sheet for evaluation. A silicone release-treated “MRU-50” manufactured by Mitsubishi Plastics, Inc. (corresponding to the separator A) was pasted to one surface of each of the obtained sealing sheets, and “TR6-75” (corresponding to the separator B) manufactured by Unitika Ltd. was pasted to the other surface. Accordingly, sealing sheets with separators on both surfaces for evaluation were obtained.

### Example 2

The sealing sheets with separators on both surfaces for evaluation were obtained in the same way as in Example 1 except “MRU-50” (non release-treated) manufactured by Mitsubishi Plastics, Inc. (corresponding to the separator B) was pasted in place of “TR6-75” manufactured by Unitika Ltd.

### Example 3

The sealing sheets with separators on both surfaces for evaluation were obtained in the same way as in Example 1 except “TR1-50” manufactured by Unitika Ltd. (corresponding to the separator B) was pasted in place of “TR6-75” manufactured by Unitika Ltd.

### Example 4

The sealing sheets with separators on both surfaces for evaluation were obtained in the same way as in Example 1 except “TR1H-50” manufactured by Unitika Ltd. (corresponding to the separator B) was pasted in place of “TR6-75” manufactured by Unitika Ltd.

### Example 5

According to the compounding ratios, the epoxy resin, the phenol resin, the thermoplastic resin, the inorganic filler, and the silane coupling agent were added in an organic solvent MEK (methylethylketone) so that the solid content concentration was 95%, and the mixture was stirred. The stirring was performed at 800 rpm rotating for 5 minutes using a planetary centrifugal mixer (manufactured by Thinky Corporation). According to the compounding ratios, the curing accelerator and the carbon black were also added in the mixture, MEK was added so that the solid content concentration was 90%, and the mixture was stirred further at 800 rpm for 3 minutes to obtain an application liquid.

The application liquid was applied onto the silicone release-treated “MRU-50”, and it was dried at 120° C. for 3 minutes to produce a sheet having a thickness of 100 μm. A plurality of the obtained sheets was pasted together at 90° C. using a roll laminator to obtain a sheet having a prescribed thickness, and the sheet was cut into pieces each having a prescribed size to obtain sealing sheets for evaluation. Specifically, the sealing sheets for evaluation were obtained having the same sizes as in Example 1. A silicone release-treated “MRU-50” manufactured by Mitsubishi Plastics, Inc. (corresponding to the separator A) was pasted to one surface of each of the obtained sealing sheets, and “TR6-75” (corresponding to the separator B) manufactured by Unitika Ltd. was pasted to the other surface.

### Example 6

The sealing sheets with separators on both surfaces for evaluation were obtained in the same way as in Example 5 except “MRU-50” (non release-treated) manufactured by Mitsubishi Plastics, Inc. (corresponding to the separator B) was pasted in place of “TR6-75” manufactured by Unitika Ltd.

### Example 7

The sealing sheets with separators on both surfaces for evaluation were obtained in the same way as in Example 5 except “TR1-50” manufactured by Unitika Ltd. (corresponding to the separator B) was pasted in place of “TR6-75” manufactured by Unitika Ltd.

### Example 8

The sealing sheets with separators on both surfaces for evaluation were obtained in the same way as in Example 5 except “TR1H-50” manufactured by Unitika Ltd. (corresponding to the separator B) was pasted in place of “TR6-75” manufactured by Unitika Ltd.

### Comparative Example 1

The sealing sheet with separators on both surfaces for evaluation was obtained in the same way as in Example 1 except the thickness of the sealing sheet was 2.0 mm and the size thereof was 10 m×10 m.

### Comparative Example 2

The sealing sheet with separators on both surfaces for evaluation was obtained in the same way as in Example 5 except the thickness of the sealing sheet was 2.0 mm and the size thereof was 10 m×10 m.

### <Measurement of Peel Strength of Separator>

The separator (corresponding to the separator B) was peeled from the sealing sheet with separators on both surfaces to measure the peel strength F2 between the sealing sheet and the separator (separator B).

Specifically, a maximum load (maximum value of the load excluding the peak top of initial measurement) was measured when peeling was performed in the following conditions, and this maximum load was obtained as the peel strength (N/20 mm wide) between the resin sheet and the separator. Then, F2 (N/20 mm)×A (m²)×t (mm) was calculated. The results are shown in Tables 1 to 3.

The peel strength F1 between the sealing sheet and the silicone release-treated “MRU-50” (corresponding to the separator A) was 0.0016 N/20 mm wide.

(Measurement Conditions of Peel Strength)

Used Apparatus: Autograph AGS-J (manufactured by Shimadzu Corporation)

### Temperature: 23° C.

Peeling angle: 180°
Peeling speed: 300 mm/min

TABLE 1
Example 1

| | | Area A [m²] | | | |
|---|---|---|---|---|---|
| TR6-75 (F2 = 0.096) | | 0.0001 | 0.01 | 0.09 | 1 |
| Thickness of | 0.2 | 0.00000192 | 0.000192 | 0.001728 | 0.0192 |
| Sealing Sheet | 0.5 | 0.0000048 | 0.00048 | 0.00432 | 0.048 |
| t [mm] | 1 | 0.0000096 | 0.00096 | 0.00864 | 0.096 |
| | 2 | 0.0000192 | 0.00192 | 0.01728 | 0.192 |

Example 2

| MRU-50 (Non | | | | | |
|---|---|---|---|---|---|
| Release-Treated) | | Area A [m²] | | | |
| (F2 = 0.264) | | 0.0001 | 0.01 | 0.09 | 1 |
| Thickness of | 0.2 | 0.00000528 | 0.000528 | 0.004752 | 0.0528 |
| Sealing Sheet | 0.5 | 0.0000132 | 0.00132 | 0.01188 | 0.132 |
| t [mm] | 1 | 0.0000264 | 0.00264 | 0.02376 | 0.264 |
| | 2 | 0.0000528 | 0.00528 | 0.04752 | 0.528 |

Example 3

| | | Area A [m²] | | | |
|---|---|---|---|---|---|
| TR1-50 (F2 = 0.422) | | 0.0001 | 0.01 | 0.09 | 1 |
| Thickness of | 0.2 | 0.00000844 | 0.000844 | 0.007596 | 0.0844 |
| Sealing Sheet | 0.5 | 0.0000211 | 0.00211 | 0.01899 | 0.211 |
| t [mm] | 1 | 0.0000422 | 0.00422 | 0.03798 | 0.422 |
| | 2 | 0.0000844 | 0.00844 | 0.07596 | 0.844 |

Example 4

| | | Area A [m²] | | | |
|---|---|---|---|---|---|
| TR1H-50 (F2 = 0.875) | | 0.0001 | 0.01 | 0.09 | 1 |
| Thickness of | 0.2 | 0.0000175 | 0.00175 | 0.01575 | 0.175 |
| Sealing Sheet | 0.5 | 0.00004375 | 0.004375 | 0.039375 | 0.4375 |
| t [mm] | 1 | 0.0000875 | 0.00875 | 0.07875 | 0.875 |
| | 2 | 0.000175 | 0.0175 | 0.1575 | 1.75 |

TABLE 2
Example 5

| | | Area A [m²] | | | |
|---|---|---|---|---|---|
| TR6-75 (F2 = 0.105) | | 0.0001 | 0.01 | 0.09 | 1 |
| Thickness of | 0.2 | 0.0000021 | 0.00021 | 0.00189 | 0.021 |
| Sealing Sheet | 0.5 | 0.00000525 | 0.000525 | 0.004725 | 0.0525 |
| t [mm] | 1 | 0.0000105 | 0.00105 | 0.00945 | 0.105 |
| | 2 | 0.000021 | 0.0021 | 0.0189 | 0.21 |

Example 6

| MRU-50 (Non | | | | | |
|---|---|---|---|---|---|
| Release-Treated) | | Area A [m²] | | | |
| (F2 = 0.37) | | 0.0001 | 0.01 | 0.09 | 1 |
| Thickness of | 0.2 | 0.0000074 | 0.00074 | 0.00666 | 0.074 |
| Sealing Sheet | 0.5 | 0.0000185 | 0.00185 | 0.01665 | 0.185 |
| t [mm] | 1 | 0.000037 | 0.0037 | 0.0333 | 0.37 |
| | 2 | 0.000074 | 0.0074 | 0.0666 | 0.74 |

Example 7

| | | Area A [m²] | | | |
|---|---|---|---|---|---|
| TR1-50 (F2 = 0.598) | | 0.0001 | 0.01 | 0.09 | 1 |
| Thickness of | 0.2 | 0.00001196 | 0.001196 | 0.010764 | 0.1196 |
| Sealing Sheet | 0.5 | 0.0000299 | 0.00299 | 0.02691 | 0.299 |
| t [mm] | 1 | 0.0000598 | 0.00598 | 0.05382 | 0.598 |
| | 2 | 0.0001196 | 0.01196 | 0.10764 | 1.196 |

Example 8

| | | Area A [m²] | | | |
|---|---|---|---|---|---|
| TR1H-50 (F2 = 0.932) | | 0.0001 | 0.01 | 0.09 | 1 |
| Thickness of | 0.2 | 0.00001864 | 0.001864 | 0.016776 | 0.1864 |
| Sealing Sheet | 0.5 | 0.0000466 | 0.00466 | 0.04194 | 0.466 |
| t [mm] | 1 | 0.0000932 | 0.00932 | 0.08388 | 0.932 |
| | 2 | 0.0001864 | 0.01864 | 0.16776 | 1.864 |

TABLE 3

| | Area A[m²] |
|---|---|
| TR6-75 | 100 |

Comparative Example 1

| | | |
|---|---|---|
| Thickness of | 2 | 19.2 |
| Sealing Sheet | | |
| t [mm] | | |

Comparative Example 2

| | | |
|---|---|---|
| Thickness of | 2 | 21 |
| Sealing Sheet | | |
| t [mm] | | |

### (Evaluation)

The silicone release-treated “MRU-50” (corresponding to the separator A) was first peeled from each of the sealing sheets with separators on both surfaces for evaluation that were produced in Examples 1 to 8 and Comparative Examples 1 and 2, and then each of the separators (corresponding to the separator B) having a different peel strength was peeled. As a result, the case in which no cracking and breaking occurred in the sealing sheet was evaluated as ◯, and the case in which at least some cracking or breaking occurred was evaluated as ×. The results are shown in Tables 4 to 6.

TABLE 4
Example 1

Area A [m²]

| | | | | |
|---|---|---|---|---|
| TR6-75 (F2 = 0.096) | 0.0001 | 0.01 | 0.09 | 1 |

| | | | | | |
|---|---|---|---|---|---|
| Thickness of | 0.2 | ◯ | ◯ | ◯ | ◯ |
| Sealing Sheet | 0.5 | ◯ | ◯ | ◯ | ◯ |
| t [mm] | 1 | ◯ | ◯ | ◯ | ◯ |
| | 2 | ◯ | ◯ | ◯ | ◯ |

Example 2

| | |
|---|---|
| MRU-50 (Non | |
| Release-Treated) | Area A [m²] |

| | | | | |
|---|---|---|---|---|
| (F2 = 0.264) | 0.0001 | 0.01 | 0.09 | 1 |

| | | | | | |
|---|---|---|---|---|---|
| Thickness of | 0.2 | ◯ | ◯ | ◯ | ◯ |
| Sealing Sheet | 0.5 | ◯ | ◯ | ◯ | ◯ |
| t [mm] | 1 | ◯ | ◯ | ◯ | ◯ |
| | 2 | ◯ | ◯ | ◯ | ◯ |

Example 3

Area A [m²]

| | | | | |
|---|---|---|---|---|
| TR1-50 (F2 = 0.422) | 0.0001 | 0.01 | 0.09 | 1 |

| | | | | | |
|---|---|---|---|---|---|
| Thickness of | 0.2 | ◯ | ◯ | ◯ | ◯ |
| Sealing Sheet | 0.5 | ◯ | ◯ | ◯ | ◯ |
| t [mm] | 1 | ◯ | ◯ | ◯ | ◯ |
| | 2 | ◯ | ◯ | ◯ | ◯ |

Example 4

Area A [m²]

| | | | | |
|---|---|---|---|---|
| TR1H-50 (F2 = 0.875) | 0.0001 | 0.01 | 0.09 | 1 |

| | | | | | |
|---|---|---|---|---|---|
| Thickness of | 0.2 | ◯ | ◯ | ◯ | ◯ |
| Sealing Sheet | 0.5 | ◯ | ◯ | ◯ | ◯ |
| t [mm] | 1 | ◯ | ◯ | ◯ | ◯ |
| | 2 | ◯ | ◯ | ◯ | ◯ |

TABLE 5
Example 5

Area A [m²]

| | | | | |
|---|---|---|---|---|
| TR6-75 (F2 = 0.105) | 0.0001 | 0.01 | 0.09 | 1 |

| | | | | | |
|---|---|---|---|---|---|
| Thickness of | 0.2 | ◯ | ◯ | ◯ | ◯ |
| Sealing Sheet | 0.5 | ◯ | ◯ | ◯ | ◯ |
| t [mm] | 1 | ◯ | ◯ | ◯ | ◯ |
| | 2 | ◯ | ◯ | ◯ | ◯ |

Example 6

| | |
|---|---|
| MRU-50 (Non | |
| Release-Treated) | Area A [m²] |

| | | | | |
|---|---|---|---|---|
| (F2 = 0.37) | 0.0001 | 0.01 | 0.09 | 1 |

| | | | | | |
|---|---|---|---|---|---|
| Thickness of | 0.2 | ◯ | ◯ | ◯ | ◯ |
| Sealing Sheet | 0.5 | ◯ | ◯ | ◯ | ◯ |
| t [mm] | 1 | ◯ | ◯ | ◯ | ◯ |
| | 2 | ◯ | ◯ | ◯ | ◯ |

Example 7

Area A [m²]

| | | | | |
|---|---|---|---|---|
| TR1-50 (F2 = 0.598) | 0.0001 | 0.01 | 0.09 | 1 |

| | | | | | |
|---|---|---|---|---|---|
| Thickness of | 0.2 | ◯ | ◯ | ◯ | ◯ |
| Sealing Sheet | 0.5 | ◯ | ◯ | ◯ | ◯ |
| t [mm] | 1 | ◯ | ◯ | ◯ | ◯ |
| | 2 | ◯ | ◯ | ◯ | ◯ |

Example 8

Area A [m²]

| | | | | |
|---|---|---|---|---|
| TR1H-50 (F2 = 0.932) | 0.0001 | 0.01 | 0.09 | 1 |

| | | | | | |
|---|---|---|---|---|---|
| Thickness of | 0.2 | ◯ | ◯ | ◯ | ◯ |
| Sealing Sheet | 0.5 | ◯ | ◯ | ◯ | ◯ |
| t [mm] | 1 | ◯ | ◯ | ◯ | ◯ |
| | 2 | ◯ | ◯ | ◯ | ◯ |

TABLE 6

| | Area A[m²] |
|---|---|
| TR6-75 | 100 |

Comparative Example 1

| | | |
|---|---|---|
| Thickness of | 2 | x |
| Sealing Sheet | | |
| t [mm] | | |

Comparative Example 2

| | | |
|---|---|---|
| Thickness of | 2 | x |
| Sealing Sheet | | |
| t [mm] | | |

### DESCRIPTION OF REFERENCE SIGNS

10 Sealing Sheet with Separators on Both Surfaces
11 Sealing Sheet
18 Sealing Sheet with a Separator on One Surface
16a Separator (Separator A)
16b Separator (Separator B)
20, 50 Laminate
22 Semiconductor Wafer
23 Semiconductor Chip
28 Sealed Body
29 Semiconductor Device

1. A sealing sheet with separators on both surfaces, comprising:
a sealing sheet,
a separator A laminated on one surface of the sealing sheet, and
a separator B laminated on the other surface of the sealing sheet; and
satisfying the following formula (1) when the peel strength between the sealing sheet and the separator A is F1, the peel strength between the sealing sheet and the separator B is F2, the thickness of the sealing sheet is t, and the area of the sealing sheet is A:
0<F2(N/20mm)×A(m²)×t(mm)<10.0(wherein,F1<F2 is satisfied.) (1)

2. A method for manufacturing a semiconductor device, comprising:
a step A of preparing a laminate in which a semiconductor chip is fixed on a support,
a step B of preparing the sealing sheet with separators on both surfaces according to claim 1,
a step C of peeling the separator A from the sealing sheet with separators on both surfaces to obtain a sealing sheet with a separator on one surface,
a step D of arranging the sealing sheet with a separator on one surface on the semiconductor chip of the laminate so that the surface where the separator A of the sealing sheet with a separator on one surface is peeled faces the surface of the semiconductor chip of the laminate,
a step E of embedding the semiconductor chip in the sealing sheet to form a sealed body in which the semiconductor chip is embedded in the sealing sheet, and
a step F of peeling the separator B.
